(19) United States
(12) Patent Application Publication
(10) Pub. No.: US 2021/0227166 A1
(43) Pub. Date: Jul. 22, 2021

(54) LOW-GAIN LOW BANDWIDTH CHARGE AMPLIFIER

(71) Applicant: Sony Semiconductor Solutions Corporation, Kanagawa (JP)

(72) Inventor: Noam Eshel, Pardesia (IL)

(21) Appl. No.: 16/746,389

(22) Filed: Jan. 17, 2020

(51) Int. Cl. H04N 5/3745

(52) U.S. Cl. CPC H04N 5/3745

(57) ABSTRACT

An image sensor and processing method therein comprises a pixel circuit configured to generate a pixel signal; a vertical signal line configured to convey the pixel signal; and a charge amplifier circuit configured to receive the pixel signal, the charge amplifier circuit being switched between a low bandwidth state and a high bandwidth state in response to a control signal.

### BACKGROUND OF THE INVENTION

### 1. Field of the Invention

This application relates generally to analog circuits. More specifically, this application relates to a system and method for noise reduction in image sensor or other electronic applications.

### 2. Description of Related Art

Image sensing devices typically consist of an image sensor, generally implemented as an array of pixel circuits, as well as signal processing circuitry and any associated control or timing circuitry. Within the image sensor itself, charge is collected in a photoelectric conversion device of the pixel circuit as a result of the impingement of light.

One example of a pixel circuit is illustrated in FIG. 1. As shown in FIG. 1, a pixel circuit 110 includes a photoelectric conversion device 111 (e.g., a photodiode), a floating diffusion FD, a storage capacitor 112, a transfer transistor 113, a reset transistor 114, a source follower transistor 115, a selection transistor 116, and a vertical signal line 117. As illustrated, the vertical signal line 117 is common to a plurality of pixel circuits within the same column. Alternatively, a particular vertical signal line may be shared among multiple columns. Gate electrodes of transfer transistor 113, reset transistor 114, and selection transistor 116 receive signals TRG, RST, and SEL, respectively. These signals may, for example, be provided by the control or timing circuitry. Light falling on photoelectric conversion device 111 is converted into an analog electrical signal.

While FIG. 1 illustrates a pixel circuit having four transistors in a particular configuration, the present disclosure is not so limited and may apply to a pixel circuit having fewer or more transistors as well as other elements, such as additional capacitors, resistors, and the like. Moreover, while FIG. 1 illustrates the source follower transistor 115 disposed between the selection transistor 116 and a power supply voltage V_{dd}, the selection transistor 116 may instead be disposed between the source follower transistor 116 and the power supply voltage V_{dd}. Additionally, the current disclosure may be extended to configurations where one or more transistors are shared among multiple photoelectric conversion devices.

The analog electrical signal generated in photoelectric conversion device 111 is retrieved by a readout circuit and is then converted to a digital value. Such a conversion typically requires several circuit components such as sample-and-hold (S/H) circuits, analog-to-digital converters (ADCs), and timing and control circuits, with each circuit component serving a purpose in the conversion. For example, the purpose of the S/H circuit may be to sample the analog signals from different time phases of the photodiode operation, after which the analog signals may be converted to digital form by the ADC.

Some image sensor designs including the above components may further include a charge amplifier placed between the vertical signal line and the S/H circuit. The inclusion of such a charge amplifier may effectively reduce noise to the input of the S/H circuit because the noise from the S/H circuit and the ADC becomes small compared to the amplified pixel signal. Furthermore, the inclusion of such a charge amplifier may reduce the bandwidth of the of the signal coming from the vertical signal line because the gain bandwidth product of a charge amplifier tends to be constant. As the gain increases, the bandwidth decreases, thus causing a reduction in the input noise to the amplifier as well as in the noise generated in the amplifier. However, in practice it may be difficult to control the bandwidth and gain of the charge amplifier solely by appropriately selecting values of various circuit components of the charge amplifier. Moreover, a charge amplifier with a low bandwidth converges slowly and may result in a lower maximum frame rate for the associated image sensor.

Therefore, there exists a need for improved noise reduction in S/H circuits, such as those found in image sensors.

### BRIEF SUMMARY OF THE INVENTION

Various aspects of the present disclosure relate to an image sensor, readout circuit therefor, and calibration method thereof.

In one aspect of the present disclosure, there is provided an image sensor that comprises a pixel circuit configured to generate a pixel signal; a vertical signal line configured to convey the pixel signal; and a charge amplifier circuit configured to receive the pixel signal, the charge amplifier circuit being switched between a low bandwidth state and a high bandwidth state in response to a control signal.

In another aspect of the present disclosure, there is provided a method of processing a pixel signal that comprises receiving, by a charge amplifier circuit, a pixel signal from a pixel circuit via a vertical signal line; and providing a control signal to the charge amplifier circuit, thereby switching the charge amplifier circuit between a low bandwidth state and a high bandwidth state.

In yet another aspect of the present disclosure, there is provided an image sensor that comprises a pixel array including a plurality of pixel circuits arranged in a plurality of rows and a plurality of columns; a vertical signal line coupled to at least a respective column of the plurality of columns, and configured to convey a pixel signal generated by a pixel circuit in the respective column; and a charge amplifier circuit configured to receive the pixel signal, the charge amplifier circuit being switched between a low bandwidth state and a high bandwidth state in response to a control signal.

In this manner, the above aspects of the present disclosure provide for improvements in at least the technical field of signal processing, as well as the related technical fields of imaging, image processing, and the like.

This disclosure can be embodied in various forms, including hardware or circuits controlled by computer-implemented methods, computer program products, computer systems and networks, user interfaces, and application programming interfaces; as well as hardware-implemented methods, signal processing circuits, image sensor circuits, application specific integrated circuits, field programmable gate arrays, and the like. The foregoing summary is intended solely to give a general idea of various aspects of the present disclosure, and does not limit the scope of the disclosure in any way.

### DESCRIPTION OF THE DRAWINGS

These and other more detailed and specific features of various embodiments are more fully disclosed in the following description, reference being had to the accompanying drawings, in which:

FIG. 1 illustrates an exemplary pixel circuit for use with various aspects of the present disclosure;

FIG. 2 illustrates an exemplary image sensor according to various aspects of the present disclosure;

FIGS. 3A-3B illustrate exemplary charge amplifiers according to various aspects of the present disclosure;

FIG. 4 illustrates an exemplary timing diagram for the charge amplifiers illustrated in FIGS. 3A-3B;

FIGS. 5A-5B illustrate other exemplary charge amplifiers according to various aspects of the present disclosure;

FIG. 6 illustrates an exemplary timing diagram for the charge amplifiers illustrated in FIGS. 5A-5B;

FIG. 7 illustrates another exemplary charge amplifier according to various aspects of the present disclosure;

FIG. 8 illustrates an exemplary timing diagram for the charge amplifier illustrated in FIG. 7;

FIGS. 9A-9B illustrate exemplary states for the charge amplifier illustrated in FIG. 7;

FIG. 10 illustrates a graph of an simulated noise pattern according to various aspects of the present disclosure;

FIG. 11 illustrates another exemplary charge amplifier according to various aspects of the present disclosure; and

FIG. 12 illustrates an exemplary timing diagram for the charge amplifier illustrated in FIG. 11.

### DETAILED DESCRIPTION

In the following description, numerous details are set forth, such as flowcharts, data tables, and system configurations. It will be readily apparent to one skilled in the art that these specific details are merely exemplary and not intended to limit the scope of this application.

Moreover, while the present disclosure focuses mainly on examples in which the processing circuits are used in image sensors, it will be understood that this is merely one example of an implementation. It will further be understood that the disclosed systems and methods can be used in any device in which there is a need to reduce noise in a signal processing or other analog circuit; for example, an audio signal processing circuit, industrial measurement and systems, and the like.

Image Sensor

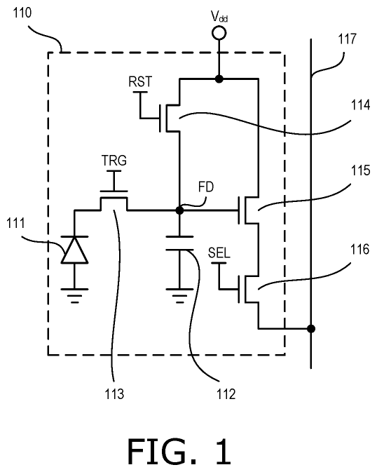

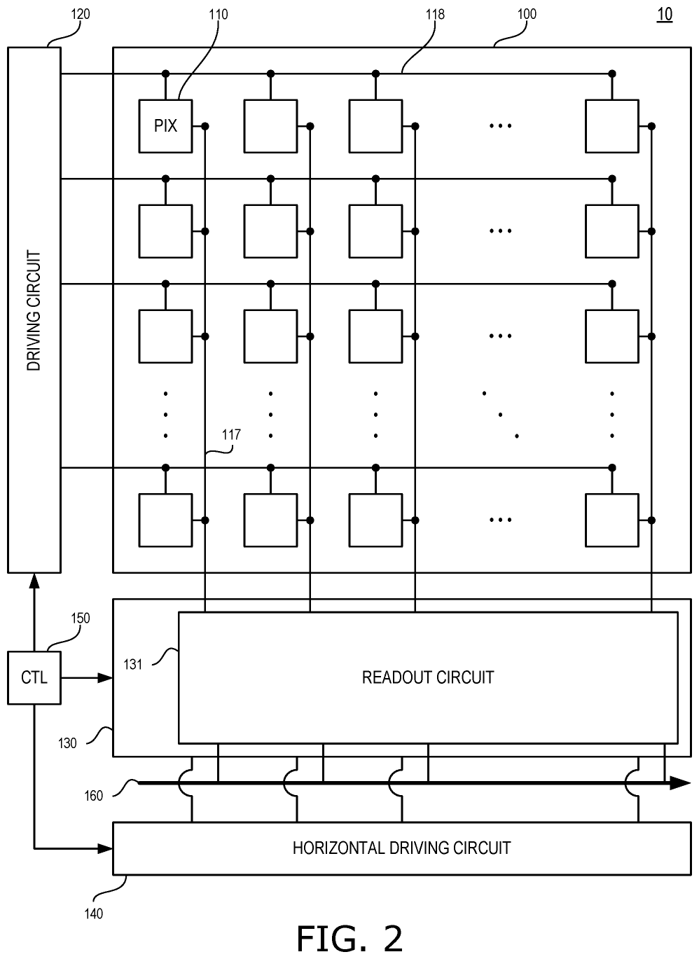

FIG. 2 illustrates an image sensor 10 according to various aspects of the present disclosure. Image sensor 10 includes an array 100 of pixel circuits 110 (e.g., the pixel circuits illustrated in FIG. 1). The pixel circuits 110 are located at intersections where horizontal signal lines 118 and vertical signal lines 117 cross one another. The horizontal signal lines 118 are operatively connected to a vertical driving circuit 120, also known as a “row scanning circuit,” at a point outside of the pixel array 100, and carry signals from the vertical driving circuit 120 to a particular row of the pixel circuits 110. Pixels in a particular column output an analog signal corresponding to an amount of incident light to the vertical signal line 117. For illustration purposes, only a subset of the pixel circuits 110 are actually shown in FIG. 2; however, in practice the image sensor 10 may have up to tens of millions of pixel circuits (“megapixels” or MP) or more.

The vertical signal line 117 conducts the analog signal for a particular column to a column circuit 130, also known as a “signal processing circuit.” While FIG. 2 illustrates one vertical signal line 117 for each column in the pixel array 100, the present disclosure is not so limited. For example, more than one vertical signal line 117 may be provided for each column, or each vertical signal line 117 may correspond to more than one column. In any case, the column circuit 130 preferably includes a readout circuit 131, which may include a plurality of individual sub-circuits and is also known collectively as “readout and ADC circuits,” which will be described in more detail below.

The column circuit 130 is controlled by a horizontal driving circuit 140, also known as a “column scanning circuit.” Each of the vertical driving circuit 120, the column circuit 130, and the horizontal driving circuit 140 receive one or more clock signals from a controller 150. The controller 150 controls the timing and operation of various image sensor components such that analog signals from the pixel array 100, having been converted to digital signals in the column circuit 130, are output via an output circuit 160 for signal processing, storage, transmission, and the like.

First Example of Amplifier Circuitry

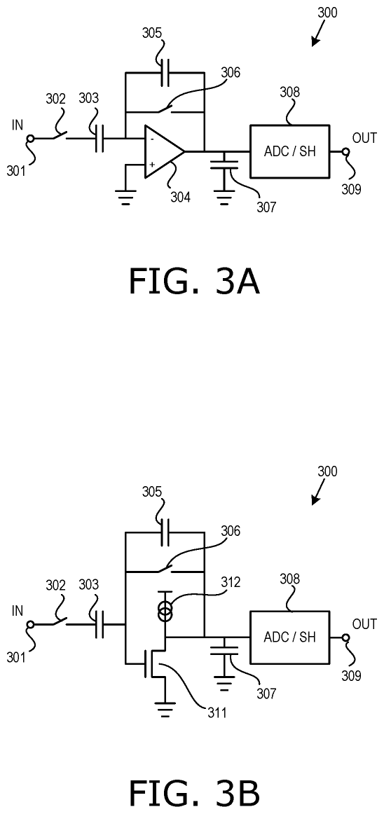

The column circuit 130 including the readout circuit 131 may include various components such as one or more charge amplifiers, ADCs, and S/H circuits. FIGS. 3A-3B illustrate one example of a readout circuit 300 in both a general implementation (FIG. 3A) and in an NMOS implementation (FIG. 3B). As illustrated in FIG. 3A, the readout circuit 300 includes an input node 301, an input switch 302, an input capacitor 303, an amplifier 304, a loop capacitor 305, a loop switch 306, a load capacitor 307, an ADC and S/H circuit 308, and an output node 309. The input node 301 receives the analog signal from the pixel circuit, which may be the same as or similar to the pixel circuit 110 illustrated in FIGS. 1-2. As such, the input node 301 may be equivalent to the vertical signal line 117.

The amplifier 304 receives the analog signal at one input terminal (as illustrated, the inverting terminal) thereof, and is grounded at the other input terminal thereof. As illustrated in FIG. 3B, the amplifier 304 may be implemented using NMOS logic by providing a transistor 311 and a current source 312 in series between a predetermined voltage (which may be a power supply voltage of the amplifier 304) and ground. The analog signal is provided to a gate terminal of the transistor 311. In some aspects of the present disclosure, the amplifier 304 may be implemented using PMOS logic or a combination of NMOS and PMOS logic. In any event, during operation, the amplifier 304 may be controlled in two stages: an auto-zero stage and a gain stage.

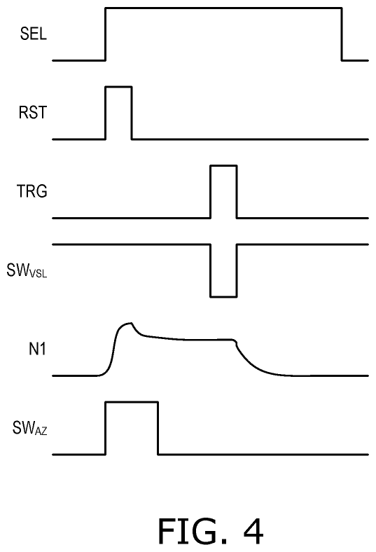

FIG. 4 illustrates an exemplary timing diagram for various control signals applied to a pixel circuit of the type illustrated in FIG. 1 and to a readout circuit of the type illustrated in FIGS. 3A-3B. Specifically, FIG. 4 illustrates the control signals SEL, RST, and TRG that are applied to the gate terminals of the selection transistor 116, the reset transistor 114, and the transfer transistor 113, respectively; and illustrates control signals SW_{VSL} and SW_{AZ} that are applied to the input switch 302 and the loop switch 306, respectively. FIG. 4 also illustrates the potential at a node N1 located between the input switch 302 and the input capacitor 303.

As illustrated in FIG. 4, when the control signal RST becomes high (thus causing the pixel circuit 110 to be reset), the potential at the node N1 rises and settles to a voltage slightly below a peak voltage. At the same time, the control signal SW_{AZ} also becomes high, thus causing an auto-zero operation in the amplifier 304. After a time, the potential at the node N1 drops to a level that reflects the charge which was stored in the photoelectric conversion device 111 during an exposure period.

In the configuration illustrated in FIGS. 3A-3B, the closed loop gain A of the amplifier 304 may be determined according to the following expression (1):

$$A = \frac{{C}_{1}}{{C}_{2}} \qquad ( 1 )$$

Above, C₁ represents the capacitance of the input capacitor 303 and C₂ represents the capacitance of the loop capacitor 305. In other words, the closed loop gain of such an amplifier is determined by the ratio of capacitances. The bandwidth BW of the amplifier 304 may be determined according to the following expression (2):

$$B W = \frac{{g}_{m}}{2 π ( {C}_{2} + {C}_{3} ) ( A + 1 )} \qquad ( 2 )$$

Above, gₘ represents the transconductance of the amplifier 304 and C₃ represents the capacitance of the load capacitor 307. Where load capacitor 307 is much larger than the loop capacitor 305 (i.e., C₃>>C₂), the bandwidth BW of the amplifier 304 is approximately equal to the following expression (3):

$$B W = \frac{{g}_{m}}{2 π {C}_{3} ( A + 1 )} \qquad ( 3 )$$

As can be seen from the above expressions, the higher the closed loop gain A is, the lower the bandwidth BW of the amplifier 304 becomes. In other words, when the closed loop gain A is high, both the noise generated by the pixel circuit 110 via the vertical signal line 117 and the noise in the amplifier 304 may be limited by the bandwidth BW. This results in a lower noise level at the output 309 of the readout circuit 300.

Second Example of Amplifier Circuitry

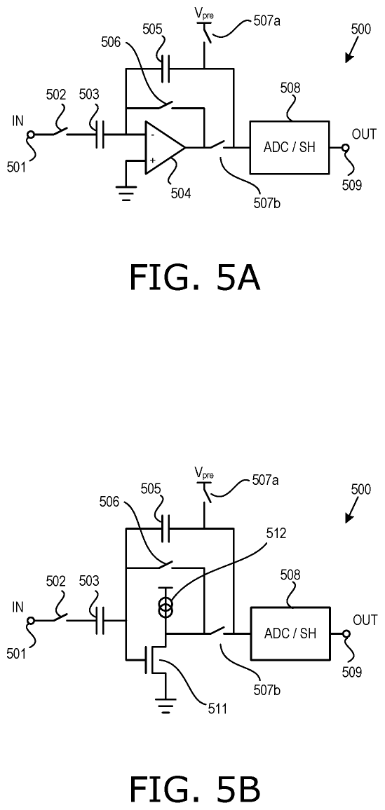

The readout circuit 300 may be modified to include a precharge capability. FIGS. 5A-5B illustrate one example of a precharge capable readout circuit 500 in both a general implementation (FIG. 5A) and in an NMOS implementation (FIG. 5B). As illustrated in FIG. 5B, the readout circuit 500 includes an input node 501, an input switch 502, an input capacitor 503, an amplifier 504, a loop capacitor 505, a loop switch 506, first and second precharge switches 507a and 507b, an ADC and S/H circuit 508, and an output node 509. The first and second precharge switches 507a and 507b selectively connect or disconnect an output of the amplifier 504 to a predetermined voltage Vₚᵣₑ. The input node 501 receives the analog signal from the pixel circuit, which may be the same as or similar to the pixel circuit 110 illustrated in FIGS. 1-2. As such, the input node 501 may be equivalent to the vertical signal line 117. Similar to the readout circuit 300 illustrated in FIGS. 3A-3B, the readout circuit 500 may further include a load capacitor (not illustrated).

As illustrated in FIG. 5B, the amplifier 504 may be implemented using NMOS logic by providing a transistor 511 and a current source 512 in series between a predetermined voltage (which may be a power supply voltage of the amplifier 504) and ground. In some aspects of the present disclosure, the amplifier 504 may be implemented using PMOS logic or a combination of NMOS and PMOS logic.

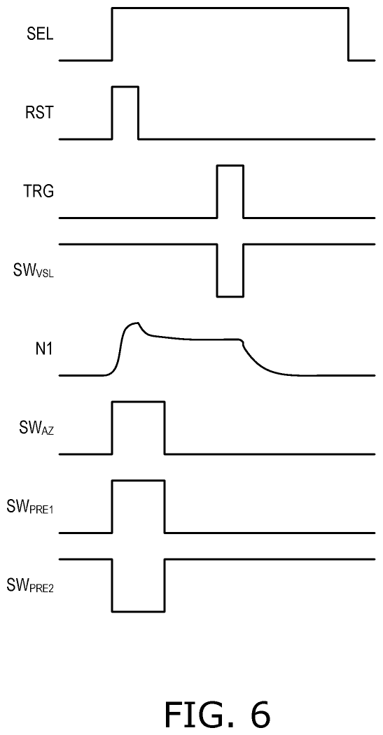

FIG. 6 illustrates an exemplary timing diagram or various control signals applied to a pixel circuit of the type illustrated in FIG. 1 and to a readout circuit of the type illustrated in FIGS. 5A-5B. Specifically, FIG. 6 illustrates the control signals SEL, RST, and TRG that are applied to the gate terminals of the selection transistor 116, the reset transistor 114, and the transfer transistor 113, respectively; and illustrates control signals SW_{VSL}, SW_{AZ}, SW_{PRE1}, and SW_{PRE2} that are applied to the input switch 502, the loop switch 506, the first precharge switch 507a, and the second precharge switch 507b, respectively. FIG. 6 also illustrates the potential at a node N1 located between the input switch 502 and the input capacitor 503.

As illustrated in FIG. 6, when the control signal RST becomes high (thus causing the pixel circuit 110 to be reset), the potential at the node N1 rises and settles to a voltage slightly below a peak voltage. At the same time, the control signal SW_{AZ} also becomes high, thus causing an auto-zero operation in the amplifier 504. Furthermore, at this time the control signal SW_{PRE1} becomes high and the control signal SW_{PRE2} becomes low. Therefore, the first precharge switch 507a is closed and the loop capacitor 505 (and therefore the ADC load) is precharged to a level Vₚᵣₑ during the auto-zero stage.

Third Example of Amplifier Circuitry

The noise performance of a readout circuit having a charge amplifier configuration may be further modified by implementing a split-gain mode and/or a low-bandwidth-low-noise mode, as will be described in more detail below.

For example, instead of using two operating modes as described above, in which an auto-zero mode and a gain mode are implemented, a split-gain mode may be used. In a split-gain mode, the gain phase may be split into two steps. In the first step, a fast settling period of the circuit is configured. In the second step, the circuit is configured for a low-bandwidth low-noise period. In the low-bandwidth low-noise period, a low-pass filter is added into the loop gain in order to reduce the overall bandwidth during that time.

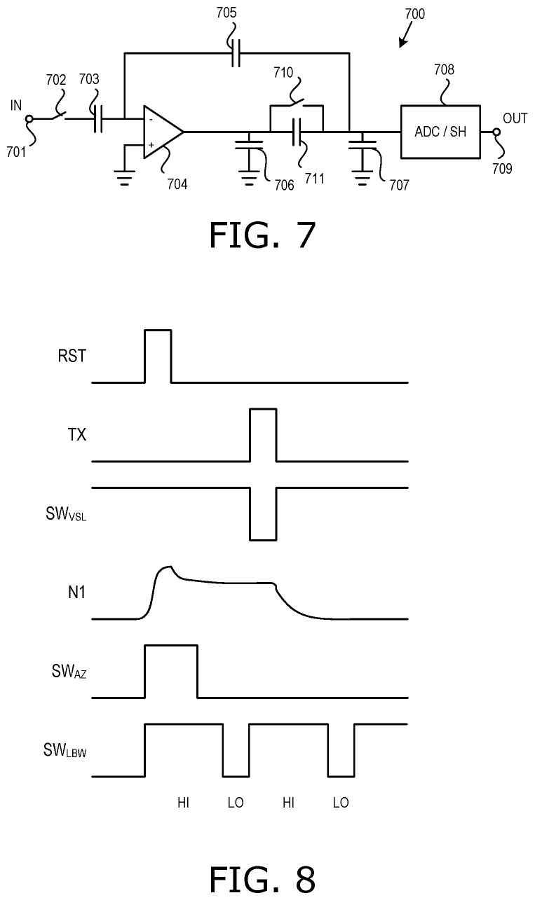

FIG. 7 illustrates an exemplary readout circuit 700 that implements these features. The readout circuit 700 includes an input node 701, an input switch 702, an input capacitor 703, an amplifier 704, a loop capacitor 705, a ground capacitor 706, a load capacitor 707, an ADC and S/H circuit 708, an output node 709, a low-bandwidth switch 710, and a low-bandwidth capacitor 711. The readout circuit 700 may further include a loop switch (not illustrated). As can be seen, in comparison to the readout circuit 300 illustrated in FIG. 3A, the readout circuit 700 further includes two additional capacitors (the ground capacitor 706 and the low-bandwidth capacitor 711) and an additional switch (the low-bandwidth switch 710). The low-bandwidth switch 710 may be operated according to a control signal SW_{LBW}. In a practical implementation, the ground capacitor 706 may be mostly or entirely provided by the parasitic capacitance of the metal routings between the amplifier 704 and the ADC and S/H circuit 708. In this manner, only a small physical ground capacitor 706, if any, may be required in practical implementations.

The input node 701 receives the analog signal from the pixel circuit, which may be the same as or similar to the pixel circuit 110 illustrated in FIGS. 1-2. As such, the input node 701 may be equivalent to the vertical signal line 117. The amplifier 704 receives the analog signal at one input terminal (as illustrated, the inverting terminal) thereof, and is grounded at the other input terminal thereof. The amplifier 704 may be implemented using NMOS logic, PMOS logic, or a combination of NMOS and PMOS logic.

In the readout circuit 700, the closed loop gain A (see expression (1) above) is set such that the noise in the ADC and S/H circuit 708 is reduced to a sufficient level while still allowing for fast settling. Preferably, a sufficient level may be defined as a level in which the noise of the ADC and S/H circuit 708 divided by the gain ratio A is lower than other noises in the system.

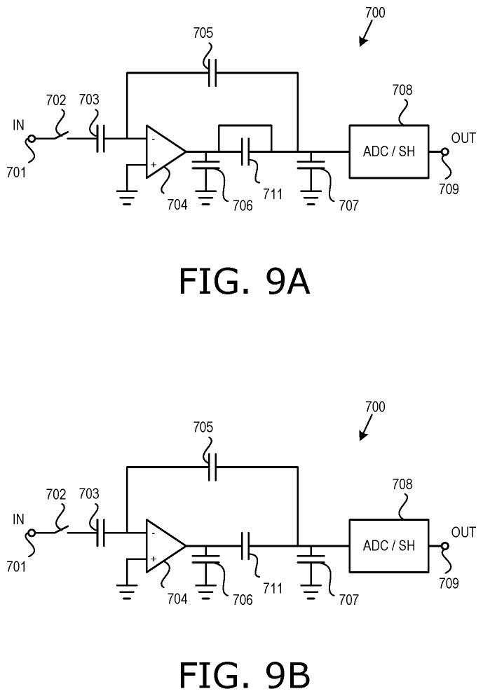

The readout circuit 700 may be operated to implement the split-gain mode having the two steps noted above. This mode is illustrated in FIGS. 8 and 9A-9B. FIG. 8 illustrates the control signals SEL, RST, and TRG that are applied to the gate terminals of the selection transistor 116, the reset transistor 114, and the transfer transistor 113, respectively; and illustrates control signals SW_{VSL}, SW_{AZ}, and SW_{LBW} that are applied to the input switch 702, the loop switch, and the low-bandwidth switch 710, respectively. FIG. 8 also illustrates the potential at a node N1 located between the input switch 702 and the input capacitor 703.

As noted above, the gain phase is split into two steps. In the first step, the control signal SW_{LBW} is high, such that the low-bandwidth switch 710 is closed. This configuration is illustrated in FIG. 9A, which shows that the low-bandwidth capacitor 711 is shorted during this period. This corresponds to a high-bandwidth stage or state during which the signal from the pixel can settle comparatively quickly. The bandwidth BW of the amplifier 704 during this period may be determined according to the following expression (4):

$$B W = \frac{{g}_{m}}{2 π ( {C}_{3} + {C}_{4} ) ( A + 1 )} \qquad ( 4 )$$

Above, gₘ represents the transconductance of the amplifier 704, C₃ represents the capacitance of the load capacitor 707, and C₄ represents the capacitance of the ground capacitor 706.

During the second step, the control signal SW_{LBW} is low, such that the low-bandwidth switch 710 is open. This configuration is illustrated in FIG. 9B. This corresponds to a low-bandwidth stage or state during which a low-pass filter is effectively inserted between the output of amplifier 704 and the load capacitor 707. The low-pass filter is formed by ground capacitor 706, load capacitor 707, and low-bandwidth capacitor 711. The feedback in the amplifier 704 is taken from the load capacitor 707 via the loop capacitor 705. In practical implementations, it may be desirable to choose the value of the low-bandwidth capacitor 711 to be a few times smaller than the values of the ground capacitor 706 and the load capacitor 707. In such an implementation, the bandwidth BW of the amplifier 704 during this period may be determined according to the following expression (5):

$$B W = \frac{{g}_{m}}{2 π {C}_{4} ( A + 1 ) ( \frac{{C}_{3} + {C}_{5}}{{C}_{5}} )} \qquad ( 5 )$$

Above, C₅ represents the capacitance of the low-bandwidth capacitor 711.

As illustrated in FIG. 8, the control signal SW_{LBW} switches between high and low, such that the readout circuit 700 alternates between the high-bandwidth stage and the low-bandwidth stage. In this manner, the high-bandwidth stage allows the signal from the pixels to settle quickly while still offering some noise reduction from the closed loop gain A. In the low-bandwidth stage, the noise from the pixel and the amplifier 704 is further reduced due to the presence of the additional low-pass filter in the readout circuit 700. Therefore, the split-gain mode allows for both fast settling and low noise, such that any tradeoff between noise and settling time or dynamic range is greatly improved.

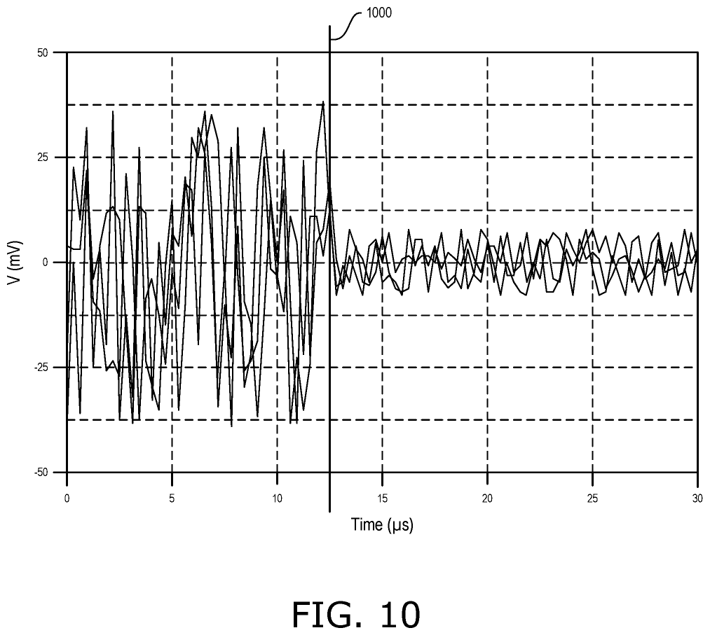

FIG. 10 illustrates a noise simulation of the readout circuit 700, centered around a time 1000 at which the readout circuit 700 transitions from the high-bandwidth stage to the low-bandwidth stage. As is apparent from FIG. 10, the noise is significantly reduced by switching to the low-bandwidth stage.

Fourth Example of Amplifier Circuitry

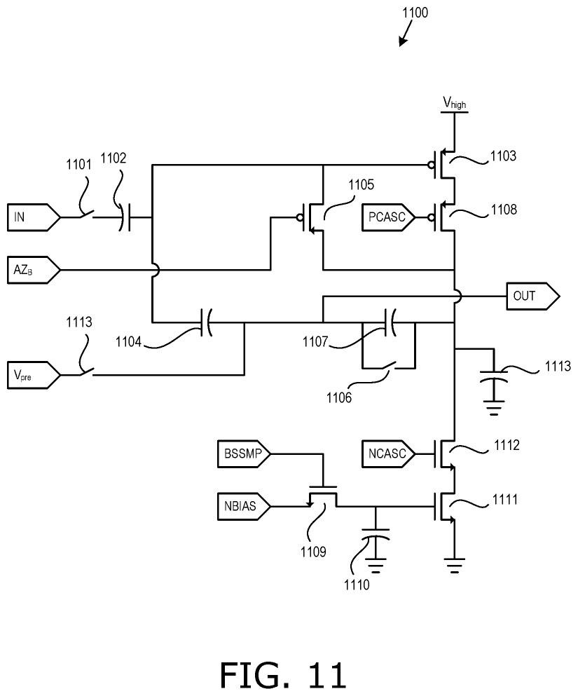

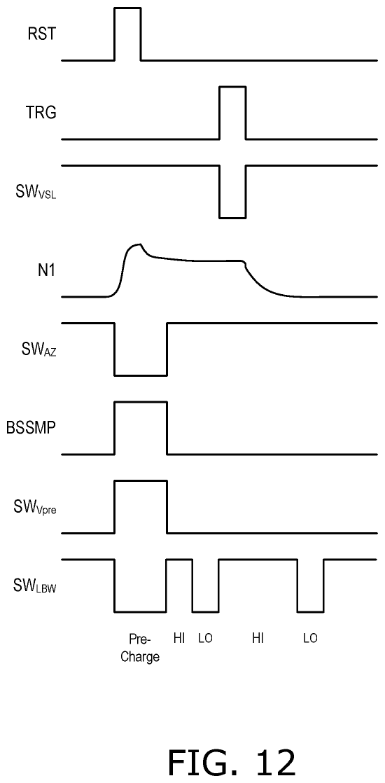

The readout circuit 700 may be modified to include a precharge capability. FIGS. 11-12 illustrate one example of a precharge capable readout circuit 1100. As illustrated in FIG. 11, the readout circuit 1100 includes an input node, an input switch 1101, an input capacitor 1102, a first amplifier transistor 1103, a loop capacitor 1104, a loop switching transistor 1105, a low-bandwidth switch 1106, a low-bandwidth capacitor 1107, and a first selection transistor 1108. The readout circuit 1100 further includes a biasing circuit formed by a sampling transistor 1109, a first bias capacitor 1110, a second amplifier transistor 1111, a second selection transistor 1112, and a second bias capacitor 1113. Thus, the readout circuit 1100 utilizes a cascade of PMOS and NMOS transistors to increase the amplifier gain. Precharge capability is provided via a precharge voltage source and a precharge switch 1113. While FIG. 11 illustrates particular circuit components to implement the above elements (for example, polarized capacitors and NMOS or PMOS transistors), the present disclosure is not so limited. In some implementations, the power supply voltage V_{high} is provided by a regulated power supply voltage source.

The input node 1101 receives the analog signal from the pixel circuit, which may be the same as or similar to the pixel circuit 110 illustrated in FIGS. 1-2. As such, the input node 1101 may be equivalent to the vertical signal line 117. As illustrated in FIG. 11, the precharge voltage Vₚᵣₑ is provided to the loop capacitor 1104 when the precharge switch 1113 is closed.

FIG. 12 illustrates the control signals RST and TRG that are applied to the gate terminals of the reset transistor 114 and the transfer transistor 113, respectively; and illustrates control signals SW_{VSL}, SW_{AZ}, BSSMP and SW_{LBW} that are applied to the input switch 1101, the loop switching transistor 1105, the sampling transistor 1109, and the low-bandwidth switch 1106, respectively. FIG. 12 further illustrates a control signal SW_{Vpre} that is applied to the precharge switch 1113.

When the control signal SW_{Vpre} is high, the precharge switch 1113 is closed and thus the precharge voltage Vₚᵣₑ is provided to the loop capacitor 1104. Afterward, the readout circuit 1100 alternates between a high-bandwidth stage with the low-bandwidth switch 1106 closed (control signal SW_{LBW} high) and a low-bandwidth stage with the low-bandwidth switch 1006 open (control signal SW_{LBW} low). Therefore, in a similar manner to that described above, the readout circuit 1100 may achieve both fast settling and low noise. To provide low noise output, the current source voltage NBIAS is sampled (control signal BSSMP high) for lower noise in pixel CDS readout operation.

### CONCLUSION

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. An image sensor, comprising:
a pixel circuit configured to generate a pixel signal;
a vertical signal line configured to convey the pixel signal; and
a charge amplifier circuit configured to receive the pixel signal, the charge amplifier circuit alternating between only two predetermined bandwidth states in response to a single control signal, the only two predetermined bandwidth states including a low bandwidth state and a high bandwidth state in response to a control signal.

2. The image sensor according to claim 1, wherein the charge amplifier circuit includes an amplifier coupled to the vertical signal line, a capacitor coupled to an output of the amplifier, and a switch coupled between a first electrode of the capacitor and a second electrode of the capacitor.

3. The image sensor according to claim 2, wherein the single control signal is configured to open the switch in the low bandwidth state and to close the switch in the high bandwidth state.

4. The image sensor according to claim 2, wherein the charge amplifier circuit includes a feedback loop between an output of the charge amplifier circuit and an input of the amplifier.

5. The image sensor according to claim 1, wherein a settling time of the charge amplifier circuit in the high bandwidth state is shorter than in the low bandwidth state.

6. The image sensor according to claim 1, wherein the charge amplifier circuit is configured to alternate between the low bandwidth state and the high bandwidth state.

7. The image sensor according to claim 1, further comprising an analog-to-digital conversion circuit coupled to an output of the charge amplifier circuit.

8. The image sensor according to claim 1, further comprising a precharge circuit configured to supply a precharge voltage to an output of the charge amplifier circuit.

9. A method of processing a pixel signal, comprising:
receiving, by a charge amplifier circuit, a pixel signal from a pixel circuit via a vertical signal line; and
providing a single control signal to the charge amplifier circuit, thereby alternating the charge amplifier circuit between only two predetermined bandwidth states in response to a control signal, the only two predetermined bandwidth states including a low bandwidth state and a high bandwidth state.

10. The method according to claim 9, wherein the charge amplifier circuit includes an amplifier coupled to the vertical signal line, a capacitor coupled to an output of the amplifier, and a switch coupled between a first electrode of the capacitor and a second electrode of the capacitor.

11. The method according to claim 10, wherein the single control signal switches the charge amplifier circuit to the low bandwidth state by opening the switch, and switches the charge amplifier circuit to the high bandwidth state by closing the switch.

12. The method according to claim 10, further comprising providing a feedback loop between an output of the charge amplifier circuit and an input of the amplifier.

13. The method according to claim 9, wherein a settling time of the charge amplifier circuit in the high bandwidth state is shorter than in the low bandwidth state.

14. The method according to claim 9, wherein the switching the charge amplifier circuit includes alternating the charge amplifier circuit between the low bandwidth state and the high bandwidth state.

15. The method according to claim 9, further comprising converting an output of the charge amplifier circuit from an analog signal to a digital signal.

16. The method according to claim 15, further comprising sampling and holding the digital signal.

17. The method according to claim 9, further comprising supplying a precharge voltage to an output of the charge amplifier circuit.

18. An image sensor, comprising:
a pixel array including a plurality of pixel circuits arranged in a plurality of rows and a plurality of columns;
a vertical signal line coupled to at least a respective column of the plurality of columns, and configured to convey a pixel signal generated by a pixel circuit in the respective column; and
a charge amplifier circuit configured to receive the pixel signal, the charge amplifier circuit alternating between only two predetermined bandwidth states in response to a single control signal, the only two predetermined bandwidth states including a low bandwidth state and a high bandwidth state in response to a control signal.

19. The image sensor according to claim 18, wherein the charge amplifier circuit includes an amplifier coupled to the vertical signal line, a capacitor coupled to an output of the amplifier, and a switch coupled between a first electrode of the capacitor and a second electrode of the capacitor.

20. The image sensor according to claim 18, wherein the vertical signal line is coupled to multiple columns of the plurality of columns.
